(19) United States
(12) Patent Application Publication
(10) Pub. No.: US 2011/0053372 A1
(43) Pub. Date: Mar. 3, 2011

(54) Low Temperature Surface Preparation for Removal of Organometallic Polymers in the Manufacture of Integrated Circuits

(75) Inventors: Srinivas Raghavan, Allen, TX (US); Kalyan Cherukuri, Allen, TX (US); Murlidhar Bashyam, Richardson, TX (US); Richard A. Faust, Dallas, TX (US)

(73) Assignee: TEXAS INSTRUMENTS INCORPORATED, Dallas, TX (US)

(21) Appl. No.: 12/549,538

(22) Filed: Aug. 28, 2009

(51) Int. Cl. H01L 21/3205

(52) U.S. Cl. 438/669; 257/E21.295

(57) ABSTRACT

A method of removing photoresist from a surface during the manufacture of an integrated circuit. Organometallic polymers and monomers are formed during the etch of a hard mask material defining the locations of a metal-bearing film, such as tantalum nitride, when photoresist is used to mask the hard mask etch. These organometallic polymers and monomers as formed are not fully cross-linked. A liquid phase solution of sulfuric acid and hydrogen peroxide used to remove the photoresist also removes these not-fully-cross-linked organometallic polymers and monomers, thus preventing the formation of stubborn contaminants during subsequent high temperature processing.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

This invention is in the field of integrated circuit manufacture. Embodiments of this invention are more specifically directed to the removal of mask material in connection with the formation of metallic structures in integrated circuits.

In recent years, the variety of materials used in the formation of integrated circuits has broadened, so as to take advantage of the properties of certain materials in the continued improvement of device performance and the continued reduction in “chip” area required for realization of a circuit function. Of course, the presence of a number of different materials tends to complicate the manufacturing process involved in formation of the integrated circuit, particularly from the standpoint of residues and contaminants generated by various materials. A particular source of such residues comes from the chemical removal, in whole or in part, of the various layers involved in manufacturing the integrated circuit.

FIGS. 1a through 1e illustrate the fabrication of an example of an integrated circuit according to a conventional manufacturing process. At the stage in the manufacture shown in FIG. 1a, isolation dielectric 6 is disposed at a surface of substrate 2, which is a semiconductor body at a surface of a wafer at which an integrated circuit is to be formed. As known in the art, isolation dielectric 6 at the surface of substrate 2 serves to electrically isolate various doped regions (e.g., wells, heavily-doped regions such as source and drain regions, and collector and base regions) that are formed at the surface of substrate 2 and serve as part of the circuit being formed. These doped regions are thus present within substrate 2, but are not shown in the cross-sectional views of FIGS. 1a through 1d either for the sake of clarity, or because such regions are located elsewhere in the device away from the section illustrated in FIG. 1a. Polycrystalline silicon (polysilicon) elements 4a, 4b, are formed and pattered at the surface of isolation dielectric 6. In this example, polysilicon element 4a will constitute a lower plate of a planar capacitor, and polysilicon elements 4b constitute conductors in the integrated circuit, connecting various devices. At locations of the integrated other than that shown in FIG. 1a, polysilicon elements 4 that overlie a thin gate dielectric layer rather than isolation dielectric 6 will constitute gate electrodes of metal-oxide-semiconductor (MOS) transistors.

Capacitor dielectric 8 is formed of an insulative material, such as silicon nitride or silicon oxide, in a layer over polysilicon elements 4 and isolation dielectric 6, and conductor layer 10 is formed over capacitor dielectric 8. Conductor layer 10 in this example is formed of a metal, metal alloy, or metal compound, for example aluminum, copper, copper-doped aluminum, tungsten, tantalum, or conductive compounds of metals such as nitrides or silicides of metals. In this example, conductor layer 10 will be photolithographically patterned and etched to define a top plate of the planar capacitor having polysilicon element 4a as its lower plate, with a film of capacitor dielectric 8 between these two plates. As such, hard mask layer 12, for example formed of silicon nitride, is formed over conductor layer 10, and photoresist 14 is formed over hard mask layer 12. In the state of manufacture illustrated in FIG. 1a, photoresist 14 has been patterned (selective exposed and developed) to no longer protect those portions of hard mask layer 12 that are to be removed before the etch of conductor layer 10.

FIG. 1b illustrates the structure after hard mask etch has been performed, for example by a plasma etch (“dry etch”) involving a conventional etchant for silicon nitride or such other material used for hard mask 12. As such, those portions of hard mask layer 12 that were not protected by photoresist 14 are removed by the etch, and photoresist 14 itself is eroded somewhat by the hard mask etch. Some of conductor layer 10 is also consumed by this hard mask etch, considering that conventional hard mask etch chemistries are not perfectly selective relative the material of conductor layer 10.

Following the hard mask etch, photoresist 14 is removed from the surface of the structure. According to this conventional manufacturing process, photoresist 14 is removed by a conventional high temperature plasma ash, which effectively burns off the organic material of photoresist 14. However, as known in the art, residue 15 of an organometallic polymer is formed at those locations at which photoresist 14 was present prior to the ash, and remains over the surface of the structure after this removal of photoresist 14, as shown in FIG. 1c. In addition, residue 15 tends to also form along the sidewalls of structures such as those at the locations of polysilicon elements 4b, also as shown in FIG. 1c.

FIG. 1d is a photomicrograph of an actual structure, in plan view, as observed by way of scanning electron microscopy, at a point in its manufacture corresponding to that of FIG. 1c. The photomicrograph of FIG. 1d illustrates several parallel polysilicon elements 4a, after removal of photoresist 14 and with hard mask layer 12 in place on the top surface of each of polysilicon elements 4a. Filaments of residue 15 on the top surface of many of these polysilicon elements 4a is evident in the photomicrograph, particularly at the surface of the interior ones of polysilicon elements 4a in this group. As mentioned above, and as evident by the slightly rounded corners and soft lines of polysilicon elements 4a in this photomicrograph, residue 15 is present to some extent on the sidewalls of each of polysilicon elements 4a.

Especially in some cases, residue 15 has proven to be very difficult to remove by way of conventional cleaning processes. One example of a stubborn residue 15 occurs with conductor layer 10 formed of tantalum nitride, in which case residue 15 is an organometallic polymer with tantalum as the metal constituent. As such, according to this conventional manufacturing process, some residue 15 will remain to some extent over the surface of the structure at the point in the process at which conductor layer 10 is to be etched. Residue 15 may not necessarily be in the form of a contiguous film as suggested by FIG. 1c, but may instead remain as particles or spots on the surface of the structure, particularly in spaces between closely-spaced lines such as polysilicon elements 4b in FIG. 1c.

FIG. 1e illustrates the structure at a next stage in this conventional manufacturing process, namely following the etch of conductor layer 10, the subsequent removal of hard mask 12 from the surface of the remaining portion of conductor layer 10, and the etch of capacitor dielectric 8 (from those locations of the surface not protected by remaining portions of conductor layer 10). Because of the presence of hard mask 12, conductor layer 10 remained at the masked location overlying polysilicon element 4a and capacitor dielectric 8, thus defining a capacitor. However, contaminants 15x that are caused by organometallic polymer residue 15 remain at the surface of the structure. These contaminants 15x can include residue 15 itself, and may also include material (e.g., material from hard mask 12 or from capacitor dielectric 8) that was undesirably protected from subsequent etches by residue 15. As shown in FIG. 1e, contaminants 15x can gather in the space between closely-spaced polysilicon elements 4b, and may also remain at the surface of polysilicon element 4a.

These contaminants 15x can cause electrical failure in the eventual integrated circuit that is fabricated from the structure shown in FIG. 1e, for example by causing electrical leakage between polysilicon elements 4b, or by causing an open or resistive contact if a contact or via etched through subsequently-deposited insulator films is at the location of a remaining contaminant 15x. In any case, the presence of contaminants 15x at the surface of elements within the fabricated integrated circuit is undesirable, and cause increased defect density and the resulting yield loss.

By way of further background, plasma ashing of photoresist using “cold chuck” equipment, to maintain the wafer at a lower than usual temperature, is known in the art. Specific equipment for providing the cold chuck in a plasma ash process is thus involved in this approach.

### BRIEF SUMMARY OF THE INVENTION

Embodiments of this invention provide a method of fabricating integrated circuits in which the density of organometallic polymer contamination defects in those integrated circuits is reduced.

Embodiments of this invention provide such a method in which the formation of stubborn organometallic polymers is inhibited, facilitating the removal of those polymers or their precursors (e.g., monomers).

Embodiments of this invention provide such a method that is compatible with modern wafer fabrication process flows, and that does not require special equipment.

Other objects and advantages of embodiments of this invention will be apparent to those of ordinary skill in the art having reference to the following specification together with its drawings.

This invention may be implemented into a method of fabricating an integrated circuit including a metal-bearing conductor layer that is to be patterned and etched in which a hard mask material define the metal-bearing conductor elements formed from that layer, and where the hard mask material is itself patterned and etched by a photoresist mask. A “wet” reagent comprised of a mixture of sulfuric acid and hydrogen peroxide is used to strip the photoresist after the hard mask etch. It has been discovered that this wet photoresist strip not only removes the photoresist but also removes organometallic polymers and monomers. This wet photoresist strip avoids the high temperatures involved in conventional plasma ash processes, and thus avoids significant cross-linking of the organometallic polymer or monomers, facilitating the removal of the organometallic polymer residue.

### BRIEF DESCRIPTION OF THE SEVERAL VIEWS OF THE DRAWING

FIGS. 1a through 1c and 1e are cross-sectional views of various stages of manufacture of an integrated circuit, according to conventional manufacturing processes.

FIG. 1d is a photomicrograph obtained by scanning electron microscopy of an example of a partially-fabricated integrated circuit manufactured according to a conventional manufacturing process.

FIG. 2 is a cross-sectional and schematic view of an integrated circuit at a stage of manufacture according to a conventional manufacturing process, illustrating recognition of the source of a problem according to this invention.

FIG. 3 is a flow diagram illustrating a method of manufacturing integrated circuits according to embodiments of this invention.

FIGS. 4a and 4b are cross-sectional views of various stages of manufacture of an integrated circuit, according to embodiments of this invention.

FIG. 5 is a photomicrograph obtained by scanning electron microscopy of an example of a partially-fabricated integrated circuit manufactured according to a embodiments of this invention.

### DETAILED DESCRIPTION OF THE INVENTION

This invention will be described in connection with one or more of its embodiments, namely as implemented into a manufacturing process for fabricating a particular integrated circuit having elements formed of metal or metal compounds. However, it is contemplated that this invention may also be beneficial when applied to other processes and in connection with other applications. In particular, while an example of this invention is described in connection with the fabrication of a parallel plate capacitor in an integrated circuit, this invention is no more particularly directed to the forming of a capacitor than it is to the forming of any other integrated circuit element or structure. Accordingly, it is to be understood that the following description is provided by way of example only, and is not intended to limit the true scope of this invention as claimed.

As discussed above in connection with the Background of the Invention, conventional patterning and etching of conductor layers of metal or a metal compound often involves the use of a hard mask layer that itself is patterned and etched using photoresist as a masking material. And as also discussed above in connection with the Background of the Invention, organometallic polymers are undesirable byproducts of those conventional methods that can cause circuit failure; these organometallic polymers are difficult to clean from the structures being fabricated.

It has been discovered, in connection with this invention, that these undesirable organometallic polymers are formed in two stages in such conventional processes. More specifically, it has been discovered that these organometallic polymers are not fully cross-linked when first formed, but rather are organometallic molecules in the form of relatively short-chain polymer molecules or monomers (i.e., polymeric organometallic molecules). It is the subsequent processing of the semiconductor wafer that causes these polymers and monomers to become more completely cross-linked and therefore difficult to remove. As a result, it has been discovered, in connection with this invention, that removal of those polymers (or monomers, as the case may be) prior to their subsequent curing and more complete cross-linking can avoid the formation of the organometallic polymer contamination discussed above, and thus reduce the defect density and improve device yield relative to conventional processes.

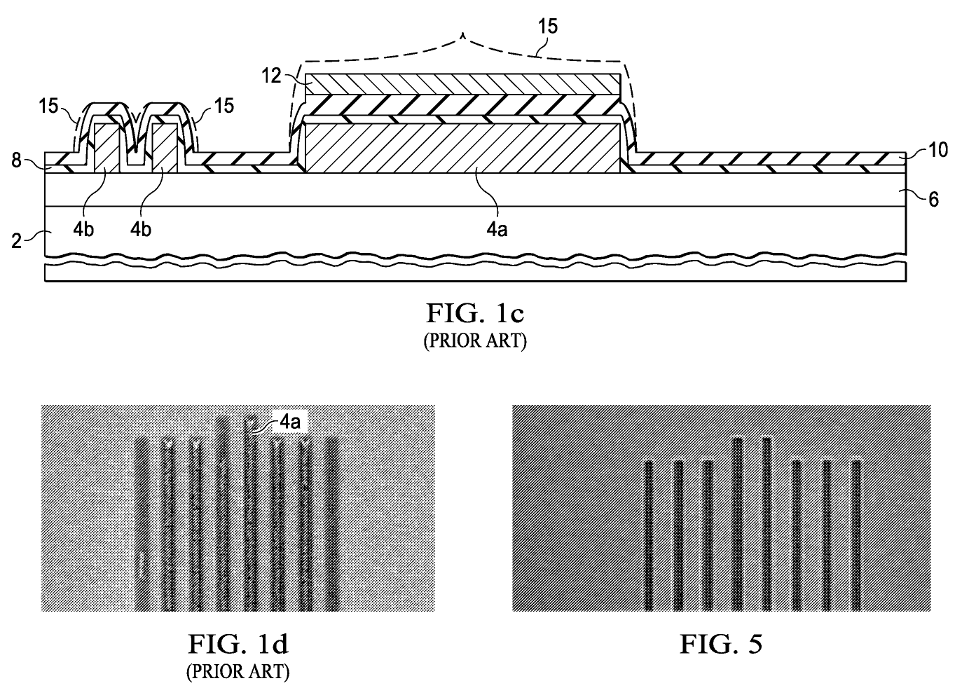

Referring now to FIG. 2, an example of the manner in which these organometallic polymers are formed, as discovered in connection with this invention, is illustrated, for purposes of understanding the operation of embodiments of this invention. FIG. 2 illustrates an example of an integrated circuit that has been partially formed according to an embodiment of this invention, in a cross-sectional view. Substrate 22 represents a semiconducting portion or body at a surface of a wafer at which the integrated circuit being manufactured in this example is being formed. Substrate 22 may constitute the entire thickness of a single-crystal silicon or other semiconductor wafer, may be formed by way of epitaxial deposition onto a semiconductor body or onto other material, or may instead constitute a semiconductor layer overlying an insulator layer supported by a “handle wafer”, according to the well-known silicon-on-insulator (SOI) technology. Of course, other physical structures at which integrated circuits are formed at a surface may alternatively be used in this structure. Various doped regions such as wells, “moat” regions into which more heavily-doped regions such as source, drain, collector, and base regions are formed, and various isolation structures separating such doped regions from one another, will typically be formed within substrate 22, depending on the design and construction of the integrated circuit. These regions are not shown in FIG. 2 for the sake of clarity of this description.

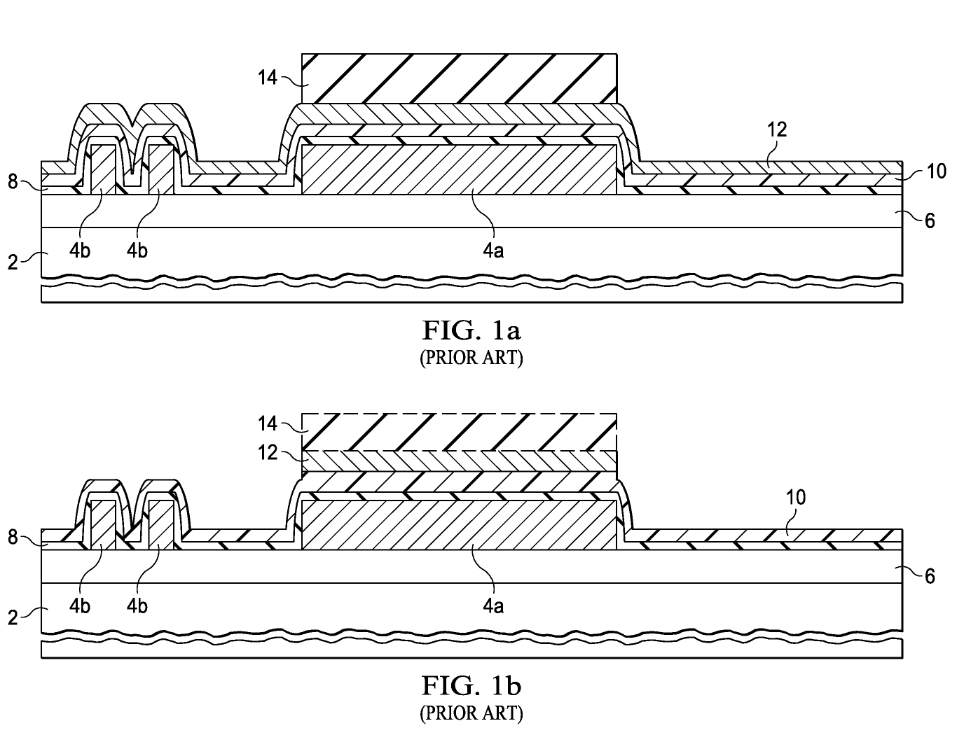

In the example of FIG. 2, isolation dielectric 26 is disposed at a surface of substrate 22, and may be formed of any conventional insulating material useful for its purpose (e.g., silicon dioxide, silicon nitride, etc.). Conventional methods for forming isolation dielectric 26 include its deposition onto the surface of substrate 22 or into trenches formed into substrate 22, and thermal oxidation of selected locations of the surface substrate 22. Polycrystalline silicon (polysilicon) elements 24a, 24b, are formed at selected locations of the surface of the structure; at the location shown in FIG. 2, these polysilicon elements 24 are insulated from substrate 22 by isolation dielectric 26. In this example, as in FIGS. 1a through 1e discussed above, polysilicon element 24a will constitute a lower plate of a planar parallel-plate capacitor to be formed. Because polysilicon elements 24b in this example overlie isolation dielectric 26, these polysilicon elements 24b operate as polysilicon-level conductors or interconnections. As known in the art, polysilicon elements 24b will constitute gate electrodes of metal-oxide-semiconductor (MOS) transistors at those locations (not shown) at which they overlie a thin gate dielectric.

In this example in which a parallel-plate capacitor is being formed, and at this stage of manufacture, a layer of capacitor dielectric 28, formed of an insulative material such as silicon nitride or silicon oxide, is disposed in a layer over polysilicon elements 24 and isolation dielectric 6. Conductor layer 30 is disposed over capacitor dielectric 28. According to embodiments of this invention, conductor layer 30 in this example is formed of a metal, metal alloy, or metal compound (or a mixture thereof); examples of the material of conductor layer 30 include aluminum, copper, copper-doped aluminum, tungsten, tantalum, and conductive compounds of metals such as nitrides or silicides of metals. As such, conductor layer 30 will be referred to, for purposes of this description and in a general sense, as being formed of a metal-bearing material. In a particular example of embodiments of this invention, conductor layer 30 is formed of tantalum nitride. And in the example shown in FIG. 2, the top plate of the parallel-plate capacitor will be formed from this conductor layer 30, with the dimensions and location of that plate defined by photolithography.

Hard mask layer 32 in this example is formed of silicon nitride, deposited by way of chemical vapor deposition over conductor layer 30. Hard mask layer 32 will mask selected portions of conductor layer 30 from etch, defining those portions of that layer that are to remain in the integrated circuit being fabricated. Hard mask layer 32 is itself patterned and etched away from other locations of the surface of the structure, with patterned photoresist 34 serving as its mask material. In the state of manufacture illustrated in FIG. 2, photoresist 34 has been previously dispensed over the surface of the structure, and has been selectively exposed and developed to be removed from those locations of the surface of hard mask layer 32 corresponding to locations at which conductor layer 30 is to be etched away.

At the point in the manufacture illustrated in FIG. 2, hard mask layer 32 has been etched to remove portions of that layer that are not protected by the patterned photoresist 34. The particular manner in which the hard mask etch is carried out depends on the material of hard mask layer 32 and of conductor layer 30, as it is desired that this etch will somewhat selectively etch hard mask layer 32 relative to conductor layer 30. For this example in which hard mask layer 32 is formed of silicon nitride and conductor layer 30 is formed of tantalum nitride, the etch of hard mask layer 32 will typically be a plasma etch (“dry etch”) involving a conventional etchant (e.g., CF₄, SF₆, CHF₃) for etching silicon nitride. As a result, hard mask layer 32 has been removed from those locations of the surface of the structure other than those locations underlying photoresist 34, and photoresist 34 itself is also eroded to some extent by this etch. Portions of conductor layer 30 at locations that are exposed after the removal of hard mask layer 32 are also consumed, to some extent, by the hard mask etch.

It has been discovered, in connection with this invention, that the metal of conductor layer 30 that is consumed in the hard mask etch reacts with the etchant of the hard mask etch, to form organometallic polymer or precursors thereof (e.g., monomers) at various locations of the structure. It has been observed, according to this invention, that the organometallic polymer and monomer molecules formed during the hard mask etch appear at the locations at which photoresist 34 remains at the time of the hard mask etch, and also appear to some extent along sidewalls of structural features (i.e., features involving some topography) at the surface of the structure being formed on substrate 22. These organometallic polymer and monomer molecules tend to not be formed at flat or field areas of the structure away from photoresist 34. FIG. 2 illustrates organometallic polymer and monomer molecules 21 at locations of this example of the structure, in a schematic sense by way of the “X” characters. As described above, the locations at which organometallic polymers and monomers form as a result of the hard mask etch include the surface of remaining photoresist 34, and also the sidewalls of polysilicon elements 24a, 24b.

It has also been discovered, in connection with this invention, that these organometallic polymer and monomer molecules 21 are not fully or significantly cross-linked at the stage in the process illustrated in FIG. 2. However, heating of the structure can cause cross-linking of organometallic polymer and monomer molecules 21 into strongly cross-linked organometallic polymer chains, which are much more difficult to remove chemically or mechanically. And it has been discovered, in connection with this invention, that conventional high temperature plasma ashing to remove photoresist 34 from the structure illustrated in FIG. 2 will cause that cross-linking of organometallic polymer and monomer molecules 21. That cross-linking results in a stubborn residue at the surface of the structure, as described above in connection with the Background of the Invention and as shown, by way of example, in the photomicrograph of FIG. 1d.

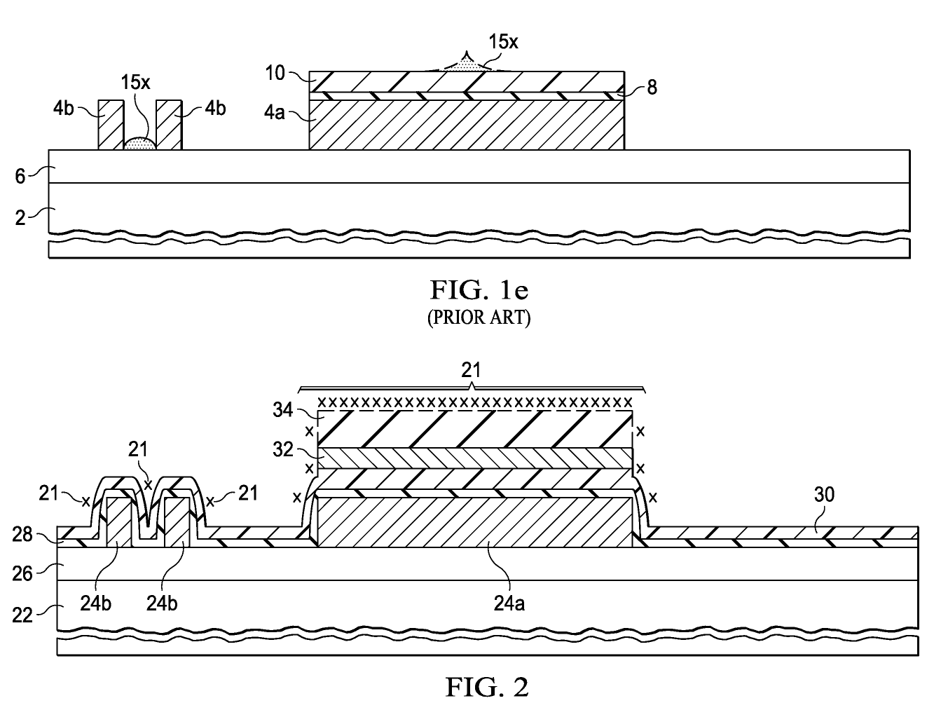

Referring now to FIG. 3, a method of fabricating integrated circuits at a semiconducting surface of substrate 22, according to an embodiment of the invention, will now be described. The fabrication of integrated circuits according to this embodiment of the invention begins with process 40, in which various initial stages of fabrication are performed to partially fabricate underlying elements in the integrated circuit in a manner that are not particularly important in connection with this embodiment of the invention, but which instead are determined by the construction of the desired integrated circuit. As such, process 40 includes such process steps as preparation and cleanup of the starting material including semiconducting portions of a surface of a wafer, formation of epitaxial layers, formation of isolation structures (e.g., isolation dielectric 26), formation of doped regions such as wells and moat regions at locations defined by the isolation structures, formation and photolithography of various interconnections, contacts, vias, and the like. It is contemplated that those skilled in the art will readily comprehend the extent of this process 40 for particular integrated circuits.

In this embodiment of the invention, polysilicon elements 24a, 24b are formed in process 42, in the conventional manner. As known in the art, polycrystalline silicon is typically deposited by way of chemical vapor deposition, and either doped in situ during its deposition or subsequently to its deposition. Conventional photolithography and etch of this polysilicon layer is also included within process 42, resulting in polysilicon elements 24a, 24b overlying isolation dielectric 26 and gate dielectric (not shown in FIG. 2) in this example, according to the design and layout of the eventual integrated circuit.

Because a parallel-plate capacitor is being formed in this example of an embodiment of this invention, process 44 then forms capacitor dielectric layer 28 overlying polysilicon elements 24; the particular manner in which process 44 is carried out depends on the material of capacitor dielectric 28 and on other factors conventional in the art. According to this embodiment of the invention, process 46 then deposits conductor layer 30 in the form of a layer of a metal-bearing material. Conductor layer 30 is metal-bearing in the sense that it is formed of a material that includes one or more metals, either in an elemental form as a single metal or an alloy or mixture of metals, or in the form of a metal compound. Examples of material suitable for use as conductor layer 30 include aluminum, copper, tungsten, titanium, tantalum, alloys or mixtures of these metals, and metal compounds such as nitrides and silicides of those metals. Tantalum nitride is a useful example of such a metal compound appropriate for use in connection with this example of an embodiment of the invention. Any one of a number of conventional methods of deposition are suitable for use in connection with process 46, depending of course on the material of conductor layer 30 and the desired thickness and other material properties; examples of these methods include evaporation, sputtering, direct reaction, and chemical vapor deposition.

In addition, as evident from this description, conductor layer 30 need not be used to form a plate of a capacitor or any other specific circuit structure. Indeed, it is contemplated that conductor layer 30 will also serve as an interconnection layer within the integrated circuit being fabricated, at locations away from that shown in FIG. 2. The parallel-plate capacitor in this description is presented merely by way of example.

As described above, a hard mask is used in the patterning and etching of conductor layer 30 into its desired pattern corresponding to the layout of the integrated circuit being formed. As known in the art, a hard mask consists of a dielectric layer or other hard material that is itself patterned and etched into the desired pattern corresponding to that of the underlying material that is eventually to be etched (e.g., in this case, conductor layer 30). The use of a hard mask is especially useful in those cases in which the underlying material is generally slow to etch; the hard mask ensures that sufficient masking material remains to protect the portion of the underlying material that is to remain in the integrated circuit being formed. In this example, tantalum nitride is a material for which use of a hard mask is beneficial. As such, in process 48, layer 32 of hard mask material is deposited over conductor layer 30, to the desired thickness required for the thickness of conductor layer 30 and the etch conditions to be encountered. The specific material of hard mask layer 32 will also depend on the material selected for conductor layer 30 and the etch chemistry. For the example of tantalum nitride as conductor layer 30, silicon nitride is a suitable material for hard mask layer 32.

As mentioned above, hard mask layer 32 is itself patterned according to the desired layout of conductor layer 30. As such, in process 50, photoresist layer 34 is applied to the desired thickness over hard mask layer 32, in the conventional manner (e.g., spinning-on). And in process 52, photoresist layer 34 is photolithographically patterned and developed in the conventional manner, so that photoresist 34 remains at the surface of the structure at those locations at which conductor layer 30 is to remain. After this patterning of photoresist 34, hard mask layer 32 is etched in process 54, masked by photoresist 34 to protect the selected locations of hard mask layer 32. The hard mask etch of process 54 is typically performed by way of a plasma etch, using an etchant species that is relatively selective so that hard mask 32 (e.g., silicon nitride) is etched at a significantly faster rate than is conductor layer 30 (e.g., tantalum nitride). As known in the art, plasma etching is typically performed in plasma reactor equipment, typically in a near-vacuum, and by exposing the wafer surface to a gas mixture in a glow discharge that excited by way of RF energy. Conventional silicon nitride etchant species include a fluorine-bearing compound, examples of which include CF₄, SF₆, and CHF₃.

FIG. 2 illustrates the state of the structure being formed, after hard mask etch process 54. As evident from FIG. 2, hard mask layer 32 is removed from all locations except from under photoresist 34, which itself is somewhat eroded by the etch. In addition to the removal of hard mask layer 32 at the unprotected locations, conductor layer 30 is also slightly consumed by the hard mask etch of process 54. Unfortunately, metal from conductor layer 30 reacts with the etchant species as conductor layer 30 is consumed, and forms organometallic polymer and monomer molecules 21 that precipitate onto the surface of the structure. As described above, it has been observed that these organometallic polymer and monomer molecules 21 tend to gather at the location of remaining elements of photoresist 34, and also along the sidewalls of structures at the surface (e.g., the sidewalls of polysilicon structures 24a, 24b). However, also as discussed above, it has been observed that organometallic polymer and monomer molecules 21 at this stage of the process are not yet strongly cross-linked.

Referring back to FIG. 3, according to this embodiment of the invention, wet resist removal process 56 is next performed to remove the remaining portions of photoresist 34. In this embodiment of the invention, wet resist removal process 56 uses a sulfuric peroxide mixture as the reagent for this process. As known in the art, wet processing is typically performed by immersing the wafer in a bath of liquid-phase reagent, and may include agitation of that bath; this wet processing may also be performed by dispensing liquid-phase reagent to the surface of a wafer cushioned by a gas, as in single-wafer machines. An example of this sulfuric peroxide mixture observed to be useful in connection with process 56 according to this embodiment of the invention is about a 1:10 volumetric ratio of sulfuric acid to hydrogen peroxide. In wet resist removal process 56, the temperature of the sulfuric peroxide mixture should be below about 70° C., to prevent undesired cross-linking of organometallic polymer and monomer molecules 21. Following application of the sulfuric peroxide mixture within wet resist removal process 56, a wet rinse of the structure can be performed, for example using a conventional “SC1” mixture (i.e., a mixture of ammonia, hydrogen peroxide, and water, for example at an approximate ratio of 1:1:5 (NH₄OH:H₂O₂:H₂O).

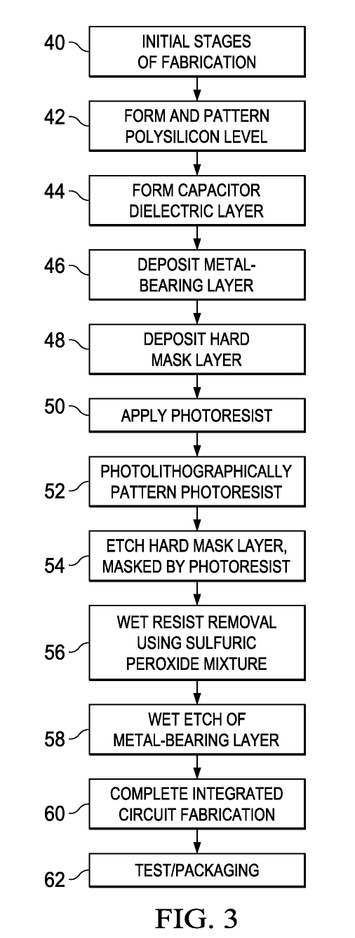

Not only does wet resist removal process 56 in this manner remove the remaining portions of photoresist 34, but according to this invention, this process 56 also removes the organometallic polymer and monomer molecules 21 present at the surface at this stage of the process. That removal of organometallic polymer and monomer molecules 21 by process 56 is facilitated by the relatively weak if not absent cross-linking of organometallic polymer and monomer molecules 21 at this stage of the process (i.e., before exposure to high temperature for any significant time). FIG. 4a illustrates an example of the structure of FIG. 2 following this wet resist removal process 56. As evident from FIG. 4a, photoresist 34 and organometallic polymer and monomer molecules 21 have been removed by the operation of process 56.

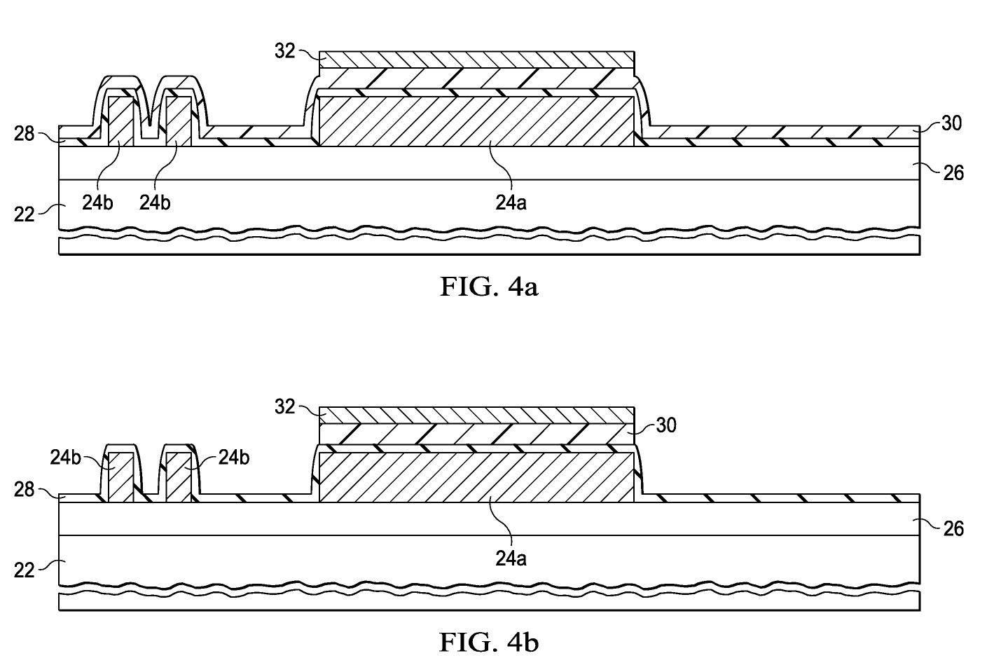

FIG. 5 is a photomicrograph of an actual structure constructed according to this embodiment of the invention, as observed by way of scanning electron microscopy, and obtained at a point in the manufacture of this structure corresponding to that of FIG. 4a. As such, FIG. 5 shows several parallel polysilicon elements 24a, after removal of photoresist 34 but with hard mask layer 32 remaining in place on their respective top surfaces. As evident from FIG. 5, no residue or other contaminant is visible as present on the top surface of any of polysilicon elements 24a in this photomicrograph, in contrast to the corresponding view of FIG. 1d in which such residue is clearly visible. In addition, the line and corner definition of these polysilicon elements 24a is quite sharp, as compared with those shown in FIG. 1d. This sharpness and resolution in these features provides further indication that the sidewalls of polysilicon elements 24a are free from organometallic polymer formation, because of the removal of organometallic polymer and monomer molecules 21 in process 56.

The manufacturing process continues with process 58, in which metal-bearing conductor layer 30 is etched in the conventional manner. According to an example of this embodiment of the invention, a wet etch is used in process 58, using a reagent suitable for etching the material of conductor layer 30 selectively relative to hard mask 32. In any event, the result of metal etch process 58 is illustrated in FIG. 4b, with conductor layer 30 remaining at locations protected by hard mask layer 32, but removed elsewhere. In the example shown in FIG. 4b, capacitor dielectric layer 28 remains at all locations of the structure, although etch process 58 may also remove this material as well, depending on the etch chemistry and the composition of conductor layer 30 and capacitor dielectric layer 28.

Following the processing that results in the definition of conductors in conductor layer 30, for example as illustrated in FIG. 4b, process 60 involved in fabricating the eventual integrated circuit is then performed to complete the fabrication of the integrated circuit, in wafer form. In general, process 60 will involve additional insulating layers and conductive layers are formed by conventional deposition and etch processes, including the etching of contacts through such insulating layers to make physical and electrical contact to doped regions in substrate 22 and to structures formed by polysilicon elements 24 and conductor layer 30, among others. Following the fabrication of all levels of metallization specified by the design of the overall integrated circuit, wafer fabrication process 60 will generally be completed by the application of a protective overcoat, through which openings to metal bond pads or other connective lands are made. Following wafer fabrication process 60, the desired electrical testing of the integrated circuits in wafer form, and such “back-end” processes as dicing of the individual circuits from the wafer, electrical test, packaging, burn-in, and additional electrical testing, are then typically performed (process 62 of FIG. 3) to result in a packaged integrated circuit that may then be implemented into end equipment. It is to be understood that such additional wafer fabrication processes 60 and test and packaging processes 62 shall not constitute a material change in the structure described herein.

According to embodiments of this invention, therefore, significant improvement in the defect density and thus improvement in the overall yield of manufactured integrated circuits result. Organometallic polymers that are typically extremely difficult to remove, once formed, are removed at a point in the manufacturing process while still in a form (short chain polymers or monomers) that enables such removal, and prior to being exposed to conditions that cause significant cross-linking. The processes involved for accomplishing this removal are highly compatible with modern integrated circuit fabrication process flows, and do not require the use of special equipment or problematic chemicals.

While this invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

What is claimed is:

1. A method of fabricating an integrated circuit at a semiconducting surface of a body, comprising the steps of:
forming a conductor layer of a metal-bearing material near the surface;
forming a hard mask layer over the conductor layer;
dispensing photoresist over the hard mask layer;
removing selected locations of the photoresist to expose portions of the hard mask layer;
then etching the exposed portions of the hard mask layer to expose portions of the conductor layer;
then applying a sulfuric peroxide mixture to the surface to remove remaining photoresist; and
then etching the exposed portions of the conductor layer.

2. The method of claim 1, wherein the metal-bearing material comprises a material selected from the group consisting of metals, metal alloys, and conductive metal compounds.

3. The method of claim 1, wherein the step of etching the exposed portions of the hard mask layer comprises:
performing a plasma etch of the exposed portions of the hard mask layer.

4. The method of claim 1, wherein the step of etching the exposed portions of the conductor layer comprises:
performing a wet etch of the conductor layer.

5. The method of claim 1, wherein the step of applying the sulfuric peroxide mixture comprises applying a liquid phase mixture of sulfuric acid and hydrogen peroxide at a relative volumetric ratio of about 1:10.

6. The method of claim 5, wherein the step of applying the sulfuric peroxide mixture comprises applying the liquid phase mixture at a temperature of less than about 70° C.

7. The method of claim 1, wherein the step of applying the sulfuric peroxide mixture comprises applying a liquid phase mixture of sulfuric acid and hydrogen peroxide at a temperature of less than about 70° C.

8. The method of claim 1, wherein step of applying the sulfuric peroxide mixture comprises:
applying a liquid phase mixture of sulfuric acid and hydrogen peroxide to the surface; and
then rinsing the surface.

9. The method of claim 1, wherein the metal-bearing material comprises tantalum nitride.

10. The method of claim 1, wherein the step of etching the exposed portions of the hard mask layer consumes a portion of the conductor layer;
wherein metal in the consumed portion of the conductor layer reacts with etchant applied in the step of etching the exposed portions of the hard mask layer, to form polymeric organometallic molecules;
and wherein the step of applying a sulfuric peroxide mixture to the surface to remove remaining photoresist also removes the polymeric organometallic molecules.

11. The method of claim 1, further comprising:
then forming one or more of each of insulating layers and conductive layers to complete an integrated circuit at the surface; and
then electrically testing the integrated circuit.

12. The method of claim 11, further comprising:
assembling the integrated circuit into a package.
